(19) United States
(12) Patent Application Publication
(10) Pub. No.: US 2021/0202282 A1
(43) Pub. Date: Jul. 1, 2021

(54) METHOD AND APPARATUS FOR TREATING A SUBSTRATE

(71) Applicant: EVATEC AG, Trubbach (CH)

(72) Inventors: Johannes Weichart, Balzers (LI); Jurgen Weichart, Balzers (LI)

(21) Appl. No.: 16/756,548

(22) PCT Filed: Sep. 14, 2018
(86) PCT No.: PCT/EP2018/074873

§ 371 Date: Apr. 16, 2020

(30) Foreign Application Priority Data
Oct. 19, 2017 (CH) 01279/17

(51) Int. Cl. H01L 21/67; H01L 21/683; H01L 21/687

(52) U.S. Cl. CPC H01L 21/67201; H01L 21/68721; H01L 21/6831; H01L 21/67103

(57) ABSTRACT

A method of treating a substrate or of manufacturing a treated substrate includes the following steps:
a) first treating a substrate in a first atmosphere of a first pressure,
b) subsequently, second treating the first treated substrate in a second atmosphere of a second pressure, wherein the second temperature of the substrate is different from the first temperature and the second pressure is lower than the first pressure,
c) between steps a) and b) locking in the first treated substrate from the first atmosphere into the second atmosphere,
d) during locking in, heating or cooling the first treated substrate from the first temperature towards the second temperature.

The present invention emanated from the following technique:

In the context of vacuum treating surfaces of workpieces or of substrates it is often necessary to degas the substrates before their surfaces are subjected to a vacuum treatment process e.g. to a thin layer deposition process, to a vacuum etching process etc. Degassing is performed in a gaseous processing atmosphere at a pressure, which is significantly higher than the pressure of a processing atmosphere as is to be applied for the subsequent vacuum treatment process. Degassing is often performed at ambient pressure. The substrates are moreover often heated by the degassing process to temperatures far too high for the subsequent vacuum treatment process. Thus, the substrates have to be cooled down between the degassing process and the beginning of the vacuum treatment process. Cooling down the substrates after the degassing process often occurs during a transport from degassing to vacuum processing. Thereby, on the one hand the footprint of the overall treatment plant is increased, and on the other hand, measures have to be taken not to spoil the respective surfaces during such cooling down phases.

A substrate transfer and cooling method is described in US 2017/0117169 A1. In a load-lock mechanism for controlling certain pressure conditions, there is provided a cooling member, which is however only used for vacuum-processed high-temperature wafers.

Coming from the addressed technique of degassing and subsequently vacuum treating surfaces of substrates, in a more generalised view, it is an object of the present invention to establish an alternative method of treating substrates, of manufacturing surface treated substrates and of a respective substrate treatment apparatus, under the following boundary conditions:
a substrate is first treated in a first atmosphere of a first pressure, resulting in a first treated substrate having a first temperature;
subsequently, the first treated substrate is second treated in a second atmosphere of a second pressure, whereby the second treating is started at a second temperature of the first treated substrate. The second treating results in the treated substrate. The second temperature is different from the first temperature and, additionally, the second pressure is lower than the first pressure.

This object is achieved by the method of treating a substrate or of manufacturing a treated substrate, comprising the following steps:
a) first treating a substrate in a first atmosphere of a first pressure, resulting in a first treated substrate having a first temperature;
b) subsequently, second treating the first treated substrate in a second atmosphere of a second pressure, starting the second treating at a second temperature of the first treated substrate and resulting in the treated substrate. The second temperature is thereby different from the first temperature and the second pressure is lower than the first pressure;
c) between steps a) and b) locking in the first treated substrate from the first atmosphere into the second atmosphere;
d) during locking in, heating or cooling the first treated substrate from the first temperature towards the second temperature.

Thus the locking-in step of the substrate, from a higher processing first pressure to a lower processing second pressure is additionally exploited to adapt the prevailing temperature of the substrate after the first treating step towards that substrate temperature required for performing the second treating. The footprint of the overall apparatus is reduced in that no additional equipment is required over equipment which is provided to perform the first and second treatings directly subsequently one another, and exploiting the conditions of the locking-in step guaranties that no substrate surface spoilage occurs.

In one variant of the method according to the invention, the first temperature is higher than the second temperature.

In one variant of the method according to the invention, the first treating is degassing. In one variant degassing can be promoted by heated nitrogen, or another gas may be used to transfer heat and to flush degassing substances.

In one variant of the method according to the invention, the first pressure is ambient atmospheric pressure, as e.g. employed for a degassing first treatment.

In spite of the fact that adaption of the substrate temperature from the first temperature towards the second temperature is performed during locking-in of the substrate to the lower pressure second treating, in some cases and according to one variant of the method according to the invention, a substrate transport is performed by a dedicated transport arrangement between the first treating and the locking in. This transport may nevertheless be significantly shorter compared with the case in which adaption of the substrate temperature was only performed during such transport, as such transport must primarily be conceived according to mechanical transport needs and not according to temperature adaption needs.

In one variant, the transport or at least a part thereof, as just addressed, is performed in ambient atmospheric pressure or even in ambient atmosphere.

In one variant of the method according to the invention the second pressure is a sub-atmospheric pressure. A sub-atmospheric pressure is deemed to be a pressure less than ambient atmospheric pressure. A synonym for sub-atmospheric pressure is vacuum. Vacuum is classified into several pressure ranges from low vacuum to medium vacuum to high and ultra high vacuum. Thereby the second pressure may be at a vacuum level at which heat transfer by convection or by conduction in the gas phase is negligible.

When pressure is reduced during locking-in from the first pressure to the second pressure at a pressure reduction rate, in one variant of the method according to the invention a heat exchange time span is provided during the locking-in, wherein during this heat exchange time span the pressure reduction rate is reduced compared with the pressure reduction rate before and/or after the addressed heat exchange time span, at least along one extended surface side of the first treated substrate.

In another variant of pressure reduction from the first pressure to the second pressure, it might not be necessary to reduce the pressure reduction rate interim, if the heat exchange is sufficiently fast and no extended heat exchange time span is needed.

In one embodiment of the method according to the invention, at least a partial contact of the substrate and of a heating or cooling surface is established during the locking-in. A partial contact can consist in the contact of the substrate to heights protruding from the heating or cooling surface, such as for example pins or webs, in cases when the reverse side of the substrate should only have pointwise contact. A partial contact can also be realized by recesses in the heating or cooling surface.

In one embodiment of the method according to the invention, the at least partial contact is a surface to surface contact of the substrate and of a heating or cooling surface, which is established during the locking-in.

In one embodiment of the method according to the invention the substrate is biased towards and onto the heating or cooling surface to establish the contact. Biasing means in particular clamping or pressing the substrate onto the heating or cooling surface.

If the substrates are rigid such as wafers, disks, printed circuit boards or rigid panels, surface to surface contact as addressed and respective biasing might not be necessary. Establishing a well-defined spacing between such a rigid substrate and the cooling or heating surface and maintaining in this spacing and during a time span during locking-in a gas pressure at which heat convection or heat conduction in the gas phase is not negligible may fasten adaption of the first temperature towards the second temperature during locking in.

If such substrates are planar, the cooling or heating surface as well will normally be planar. If such rigid substrates are nonplanar, e.g. bent or curved such as optical lenses, the shape of the cooling or heating surface is correspondingly adapted, e.g. concave or convex.

In spite of the fact that establishing a surface to surface contact between a rigid substrate and the cooling or heating surface will always improve heat exchange by additional direct heat conduction, it might only be established, if at the respective substrate area such mechanical contact is admissible.

Nevertheless and if the substrate is not rigid but rather floppy as encountered with large and thin substrates, the addressed surface to surface contact is mostly unavoidable but uncontrolled, and should be improved and controlled by the addressed biasing.

In one variant of the method according to the invention, biasing onto the heating or cooling surface is performed by at least one of mechanically and of electrostatically. One variant of “mechanically” is by means of a hold-down device, e.g. by a downholder ring or clamping ring. “Mechanically” includes also biasing by a gas-pressure difference.

In one variant of the method according to the invention, the addressed biasing comprises establishing a pressure difference Δp_{ab} between a surface of the substrate facing the heating or cooling surface and the remainder of the surface of the substrate, by applying a lower pressure pₐ at a contacting area compared to a prevailing pressure p_{b} to which the remainder of the surface of the substrate is exposed. Thereby the substrate is pressure biased by a positive pressure difference Δp_{ab}(=p_{b}−pₐ) onto the cooling or heating surface. In one variant a hold-down device might be used in addition.

In one variant the pressure difference Arab is selected to be at least 300 Pa, or in the range of 300 Pa≤Δa_{ab}≤100000 Pa, or in the range of 500 Pa≤Δp_{ab}≤10000 Pa.

In one variant the prevailing pressure p_{b} as addressed, is selected to be at least 400 Pa, or in the range of 400 Pa 100000 Pa, or in the range of 1000 Pa≤Δp_{b}≤20000 Pa.

In one variant of the method according to the invention, a desired positive or negative pressure difference Δp_{ab} is set by means of a negative feedback control loop. This comprises establishing a first pressure between a substrate and a heating and/or cooling surface in a load lock chamber and establishing a second pressure in the remaining volume of said load lock chamber and negative feedback controlling a difference of said first and second pressures on a pre-set difference value or on a pre-set difference time course at least during a predetermined time span during locking in. Thereby such negative feedback control loop or system may control both the first and the second pressures on respective values or to follow respective time courses, indirectly resulting in a control of the addressed difference. Alternatively the addressed difference may directly be negative feedback controlled on a desired value or to follow a desired time course. In latter case one of the addressed pressures, most often the second pressure, is additionally negative feedback controlled on a desired value or to follow a desired time course.

Instead of a positive pressure difference Δp_{ab}, in another variant of the method according to the invention, an inverse pressure difference with a higher pressure pₐ at a contacting area compared to a prevailing pressure p_{b} at an opposite surface side of said first treated substrate is controlled by the negative feedback control loop. This variant however needs a hold-down device to hold down the substrate against the negative pressure difference force. Such a variant can be appropriate in combination with a spacing between a rigid substrate and the cooling or heating surface and maintaining in this spacing during a time span during locking-in a gas pressure at which heat convection or heat conduction in the gas phase can improve the heat exchange. It is also possible to introduce a gas with higher heat conduction, into this spacing during heat exchange, e.g. helium or argon.

The method according to the invention comprises in a further variant removing the second treated substrate from the second treating via locking out at the same place as performing said locking in.

In one variant during the locking out, a further heating or cooling of the second treated substrate is performed. In one variant the further heating or cooling is a cooling or heating performed by same means as the cooling or heating performed during the locking in.

In one variant of the method according to the invention initiating cooling or heating, especially cooling, is performed a predetermined time span later than initiating lowering the pressure for the locking in process.

A method of heating or cooling a floppy substrate in vacuum comprises pressing said substrate onto a heating or cooling surface by generating a drop of pressure across said substrate directed towards said heating or cooling surface.

Two or more than two variants of the method according to the invention may be combined unless being inconsistent.

The object of the invention is moreover achieved by a substrate treatment apparatus, wherein the apparatus comprises:
a) a first treatment station for at least one substrate and constructed to treat said at least one substrate in a first atmosphere at a first pressure and comprising a first station output for a first treated substrate;
b) a second treatment station for at least one substrate and constructed to treat said at least one first treated substrate in a second atmosphere at a second pressure which is lower than said first pressure and comprising a second station input for a first treated substrate;
c) a load lock chamber interconnected between said first station output and said second station input;
d) a controlled heat exchange device in said load lock chamber adapted to exchange heat with a first treated substrate in said load lock chamber, controlled to be enabled as said first treated substrate is load-locked through said load lock chamber from said first treatment station to said second treatment station.

The controlled heat exchange device is e.g. controlled by at least one active heating or cooling element with adjustable temperature. The temperature may be adjustable by a flow temperature or respectively a supply temperature of a heating or cooling fluid, or by an adjustable electric element.

In one embodiment of the apparatus according to the invention, the controlled heat exchange device comprises a heating or cooling unit. In one embodiment, the controlled heat exchange device comprises a heating-cooling unit.

In one embodiment of the apparatus according to the invention the first treatment station is a degasser station. An example for a degasser station for degassing substrates is described in the patent application publication US 2016/0336204 A1 of the same applicant as the present application. Degassing is an important treatment process step e.g. for polymer matrix substrates before such substrates are treated at sub-atmospheric pressure, e.g. by one or more than one sputter deposition processes.

In one embodiment of the apparatus according to the invention, the first pressure is ambient atmospheric pressure.

In one embodiment of the apparatus according to the invention there is provided a transport arrangement interconnected between the first station output and the load lock chamber.

In one embodiment of the apparatus according to the invention the transport arrangement is designed for transporting the substrate in at least one of ambient atmospheric pressure and of ambient atmosphere.

In one embodiment of the apparatus according to the invention the second treatment station is a sub-atmospheric treatment station. Such second treatment station can be e.g. a vacuum installation with one or more vacuum process chambers located around a central vacuum transfer chamber as e.g. disclosed in the EP 2 409 317 B1.

In one embodiment of the apparatus according to the invention the heat exchange device in the load lock chamber comprises a heating and/or cooling surface, e.g. on a workpiece carrier.

A further embodiment of the apparatus according to the invention comprises a biasing arrangement constructed to bias a substrate onto the heating and/or cooling surface.

In one embodiment of the apparatus according to the invention the biasing arrangement comprises pressure control members adapted to control a pressure difference between a pressure along the heating and/or cooling surface with put-on substrate and a prevailing pressure in the load lock chamber distant from said heating and/or cooling surface.

In one embodiment of the apparatus according to the invention the pressure control members comprise a first pumping line arrangement connected by a conduit to at least one opening in the heating and/or cooling surface, and a second pumping line arrangement connected by another conduit to at least one further opening to the load lock chamber distant from said heating and/or cooling surface.

In one embodiment of the apparatus according to the invention the at least one opening in the heating and/or cooling surface branches out in a pattern of grooves in the heating and/or cooling surface.

In one embodiment of the apparatus according to the invention the first and the second pumping line arrangements are branches from a common pumping suction port.

In one embodiment of the apparatus according to the invention at least one of the first and of the second pumping line arrangements comprises a pressure-control valve or a flow-control valve.

In one embodiment of the apparatus according to the invention, a negative feedback control system is provided for controlling a pressure difference Δp_{ab} between a pressure along said heating and/or cooling surface with put-on substrate and a prevailing pressure in said load lock chamber distant from said heating and/or cooling surface to be on a desired value or to follow a desired time course.

In one embodiment of the apparatus according to the invention the heat exchange device comprises a substrate carrier with a substrate carrier surface and a rim or a clamping ring along the periphery of the substrate carrier surface. A rim or a clamping ring along the addressed periphery increase the gas flow resistance at the edge of the put-on substrate, so that less gas flows between the contacting area on the reverse side of the substrate and the remaining volume of the load lock chamber. In other words, pressure equalisation is slowed down by the pressure stage or flow resistance provided by such rim or clamping ring along the periphery of the substrate. A synonym for clamping ring is downholder ring.

In one embodiment of the apparatus according to the invention the heat exchange device comprises conduits for a heating fluid and/or for a cooling fluid.

In one embodiment of the apparatus according to the invention, the second station input is also a second station output, and the load lock chamber is constructed for bidirectional substrate handling operation. Clearly the second station may have a separate output load lock chamber, so that the input load lock chamber and the output load lock chamber would each be operated unidirectional.

In one embodiment, the apparatus of the present invention comprises in the load lock chamber:
a heating and/or cooling surface;
a substrate carrier for a substrate, a substrate on said carrier defining an interspace with said heating and/or cooling surface;
a first pressure sensor operatively connected to said interspace;
second pressure sensor operatively connected to the remainder of said load lock chamber;
a negative feedback control loop with a controller adapted to control a difference of pressures measured by said first and second pressure sensors to be equal to a pre-set pressure difference value or to follow a pre-set pressure difference time course.

### BRIEF DESCRIPTION OF THE DRAWINGS

The drawings illustrate principles of the invention and certain embodiments by means of schematic diagrams, which however do not limit the scope of the invention.

FIG. 1 shows simplified and schematically an embodiment of a substrate treatment apparatus according to the present invention.

FIG. 2 shows simplified and schematically a first treatment station as applied in one embodiment of the apparatus according to the invention.

FIG. 3 shows schematically and simplified a load lock chamber with a controlled heat exchange device and pressure control members according to an embodiment of the apparatus of the present invention.

FIG. 4 shows controlled pressure courses in a load lock chamber as controllably established in one embodiment of the apparatus according to the present invention with Δp_{ab}>0.

FIG. 5 shows controlled pressure courses in a load lock chamber as controllably established in one embodiment of the apparatus according to the present invention with Δp_{ab}<0.

FIG. 6 shows schematically and simplified a load lock chamber with a negative feedback control system for a pressure difference control according to an embodiment of the apparatus of the present invention.

FIG. 7A and FIG. 7B show simplified and schematically a rim along the periphery of the substrate carrier surface according to embodiments of the apparatus of the present invention.

FIG. 8A and FIG. 8B show simplified and schematically a hold-down device used for mechanical biasing the substrate according to a variant of the method and an embodiment of the apparatus of the present invention.

### DETAILED DESCRIPTION OF THE PICTURED EMBODIMENTS

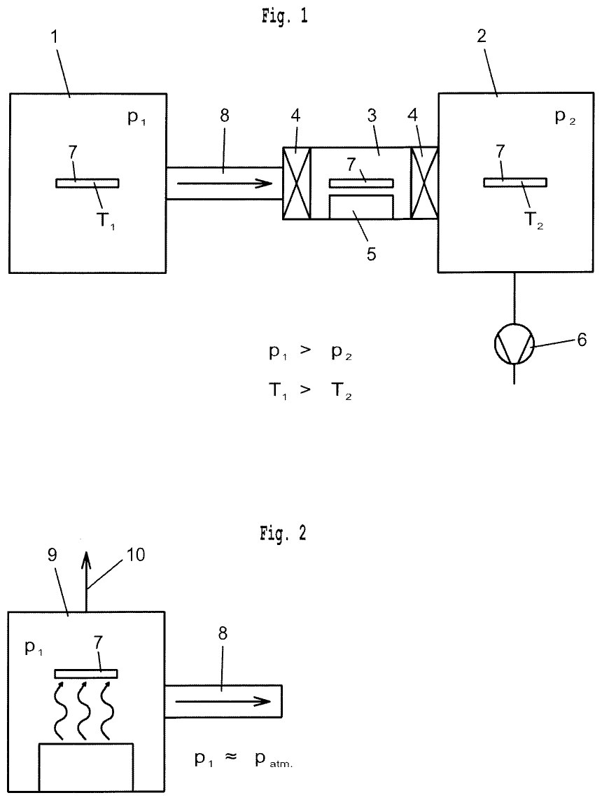

FIG. 1 is a schematic representation of a substrate treatment apparatus in accordance with an embodiment of the present invention. This substrate treatment apparatus is suitable for carrying out the method of treating a substrate or of manufacturing a treated substrate in accordance with the teachings of the present invention. The substrate treatment apparatus as shown comprises a first treatment station 1 constructed to treat at least one substrate 7 in a first atmosphere at a first pressure p₁ and resulting in a temperature T₁ of the first treated substrate 7. The substrate 7 subsequently undergoes a second treating in a second treatment station 2 starting at a second substrate temperature T₂ in a second atmosphere of a second pressure p₂. The second pressure p₂ is lower than the first pressure p₁. The lower pressure p₂ is established by a vacuum pump 6 connected to the second treatment station 2. Between a substrate output of the first treatment station 1 and a substrate input of the second treatment station 2, a load lock chamber 3 is interconnected. The load lock chamber 3 comprises load lock valves 4. The load lock chamber 3 further comprises a controlled heat exchange device 5 which is adapted to exchange heat with the substrate 7 in order to heat or to cool the first treated substrate 7 from the first temperature T₁ at least towards the second temperature T₂. In FIG. 1 the heat exchange is cooling, thus T₁ is higher than T₂. The apparatus can optionally comprise a transport arrangement 8 for transporting and handling the first treated substrate 7.

FIG. 2 shows schematically a degasser station 9 as one embodiment of a first treatment station 1 of the present invention. Degassing is an important treatment process step e.g. for polymer matrix substrates before such substrates are treated by sub-atmospheric deposition techniques in a second treating such as by one or more than one sputter deposition processes. In the degasser station 9, substrates 7 are degassed e.g. in a flow of heated nitrogen (symbolized by waved arrows). The nitrogen transfers heat to the substrates and flushes evaporated degassing products from the substrates 7 to a vent 10 of the degasser station 9. The pressure p₁ in a degasser station as well as possibly along at least a part of the transport arrangement 8, if provided, may be around ambient atmospheric pressure pₐₜₘ.

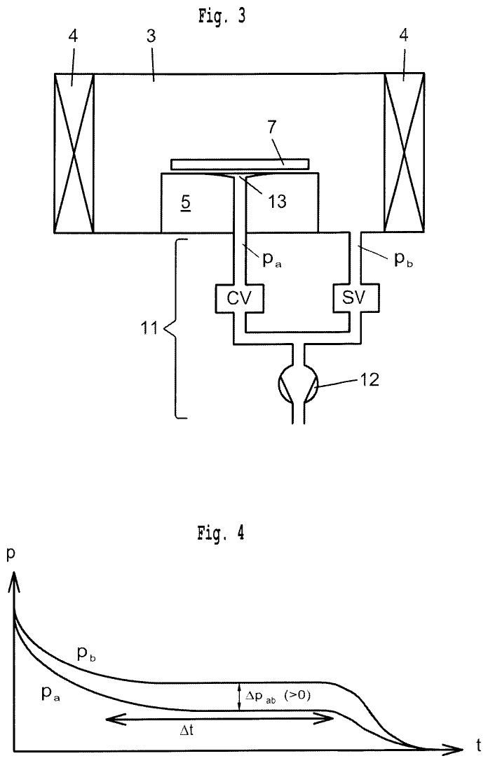

FIG. 3 shows a schematic and simplified representation of a load lock chamber 3 with a controlled heat exchange device 5 and pressure control members 11 according to an embodiment of the present invention. The load lock chamber 3 comprises the load lock valves 4. The heat exchange device 5 has the shape of a table with a heating or cooling surface. Possibly the same surface may be used for cooling and for heating, dependent on its controlled operation. The substrate 7 is put on the heating or cooling surface for heat exchange. For biasing the substrate 7 onto the heating and/or cooling surface by a pressure difference, pressure control members 11 are associated with the load lock chamber 3. In the pictured embodiment, the pressure control members 11 comprise a first pumping line arrangement which is connected by a conduit to an opening 13 in the heating and/or cooling surface. In this conduit, leading to the opening 13, the pressure pₐ which is effective at the contacting area between the put-on substrate 7 and the heating and/or cooling surface of the heat exchange device 5 can be measured if necessary (as shown in FIG. 6). The opening 13 can branch out in a pattern of grooves in the heating and/or cooling surface as adumbrated in the figure. The pressure control members 11 furthermore comprise a second pumping line arrangement connected by another conduit to the load lock chamber 3 distant from the heating and/or cooling surface. In this other conduit near the chamber respectively in the chamber, the pressure p_{b} which corresponds to the prevailing pressure in the load lock chamber 3 can be measured (as shown in FIG. 6) if necessary. In the embodiment as shown, the first and the second pumping line arrangements are branches from a suction port of a common vacuum pump 12 of the pressure control members 11, as pictured in FIG. 3. The pressure pₐ along the area on the reverse side of the substrate 7, the pressure p_{b} within the remaining volume of the load lock chamber and thus the pressure difference Δp_{ab}(=p_{b}−pₐ) are adjusted by control valves CV and SV in the pumping line arrangements. For providing pressure for biasing the substrate 7 towards and onto the heating- and/or cooling surface of the heat exchange device 5, pₐ is controlled to be lower than p_{b}. The shut-off valve SV may also be an adjustable control valve CV. One single control valve CV or SV may suffice for setting and controlling the pressure difference Δp_{ab}.

FIG. 4 illustrates a variant of a controlled pressure course in the load lock chamber 3 in accordance with a teaching of the present invention. After locking in the substrate 7 into the load lock chamber 3 and having put it on the heating and/or cooling surface of the controlled heat exchange device 5, the vacuum pump 12 of the pressure control members 11 is started with open valves CV and SV. FIG. 4 shows with two exemplary pressure curves how pₐ and p_{b} are controlled to decrease, so that a positive pressure difference Δp_{ab}(=p_{b}−pₐ)>0 for a pressure difference biasing of the substrate results. The pressure courses according to FIG. 4 provide for a surface to surface contact heat exchange between the heat exchange device 5 and the substrate 7. Surface to surface heat exchange contact provides the best possible heat transfer. According to such pressure control, the substrate is put in surface contact with the heating and/or cooling surface of the heat exchange device 5 especially during the heat exchange time span Δt with controllably reduced pressure reduction rate. The heat exchange device 5 can either be active from the beginning of locking in, or it can be activated at the beginning of the time span Δt (by controls 18 for heat exchange device 5, as shown in FIG. 6), when a lower pressure level has been reached. The latter course of action may be advantageous in the case of cooling, to avoid a humidity condensation on the first treated substrate. After the time span Δt, the valves CV and SV are fully opened again, and the load lock chamber 3 is pumped down to a low pressure which is about the same as the pressure p₂ in the second treatment station 2, to enable the subsequent transfer of the substrate 7 into the second treatment station 2.

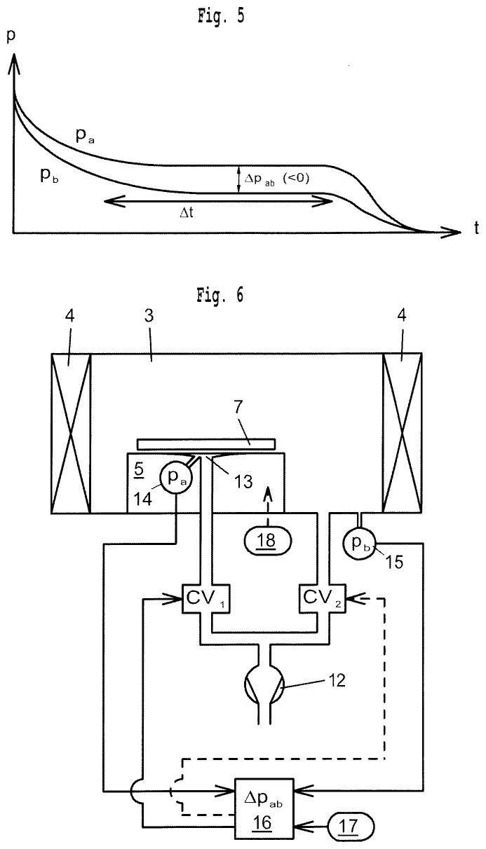

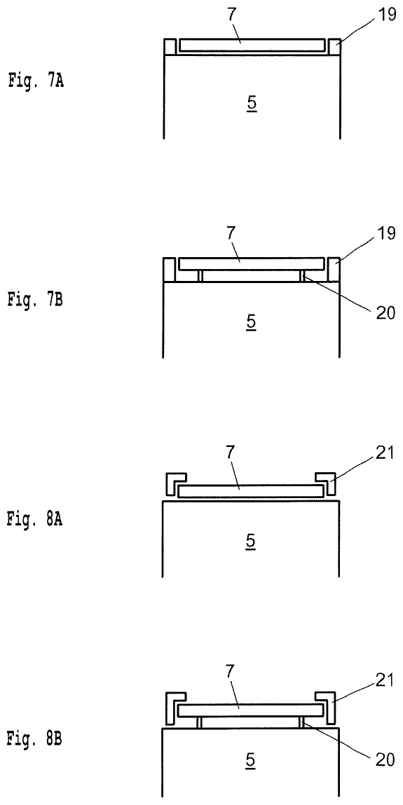

FIG. 5: If the substrate 7 does not allow mechanical contact on its reverse side, then in one variant, pressure courses inverse to those shown in FIG. 4 may be controllably established, as depicted in FIG. 5. As in this case there should remain a spacing between the reverse surface of the substrate 7 and the heating and/or cooling surface of the heat exchange device 5, gas pressure pₐ may be kept relatively high as long as possible to improve heat conduction across the gas in the addressed space. Thus pₐ is kept higher than p_{b} in that the evacuation rate in the space between the reverse side of the substrate 7 and the heating and/or cooling surface of the heat exchange device 5 is kept lower than the evacuation rate of the remainder volume of the load lock chamber 3 and is reduced at least during the heating or cooling time span, in analogy to Δt of FIG. 4. Also this control of pₐ and p_{b} may be performed by the control valves CV and/or SV as depicted in FIG. 3. Due to the negative pressure difference Δp_{ab} in this case (Δp_{ab}=p_{b}−pₐ<0), this variant however needs a hold-down device to hold down the substrate against the negative pressure difference force. Such an embodiment is shown in FIG. 8B.

FIG. 6 shows schematically and simplified a load lock chamber with pressure control members (as explained for FIG. 3) and a negative feedback control system for the pressure difference control according to an embodiment of the present invention. In addition to the depicted apparatus of FIG. 3, a feedback control system is installed here which comprises pressure sensors 14 and 15 for pₐ and p_{b}, a controller 16 with pressure measurement inputs and an output to at least one of the valves CV₁ and/or CV₂ as an adjusting member of the negative feedback control loop. By a unit 17 the desired values for pressure level and the pressure difference Δp_{ab} or the desired time course of the pressure difference Δp_{ab} is preset. The controller 16 acts on at least one of the valves CV₁, CV₂ in dependency of the control deviation i.e. the difference of the momentarily desired pressure difference, preset at the unit 17, and the momentarily prevailing pressure difference as measured, so as to establish the momentarily measured difference to be equal the momentarily desired difference as preset. The valve CV₂ can either be operated manually or by a separate control, or it can also be operatively connected with a second output of the controller 16. Furthermore FIG. 6 shows schematically and simplified controls 18 for the heat exchange device 5, by which e.g. the active heat exchange can be started at a desired point in time.

FIG. 7A and FIG. 7B: Maintaining a high enough pressure difference Δp_{ab} is facilitated by providing along the periphery of the substrate 7 an increased gas flow resistance from the overall load lock chamber volume into the volume beneath the substrate 7 or vice versa. This may be accomplished by a correspondingly constructed rim 19 along the periphery of the substrate carrier surface or, respectively the heating and/or cooling surface of the heat exchange device 5. The periphery of the substrate 7 resides in a fitting rim 19. The embodiments shown in FIG. 7A and FIG. 7B are both designed for pₐ being less than p_{b}. The opening 13 in the heat exchange device 5 for applying pₐ is not shown in FIG. 7A and FIG. 7B for convenience. In FIG. 7A the substrate 7 is in a surface to surface contact with the heating or cooling surface of the heat exchange device 5. In FIG. 7B there is only a partial contact with heights or protrusions 20, e.g. pins 20, protruding from the heating or cooling surface, showing a case where the reverse side of the substrate should only have pointwise contact.

FIG. 8A and FIG. 8B show variants and embodiments of biasing a substrate 7 with a hold-down device 21, e.g. a downholder ring or clamping ring 21, which grips along and on the periphery of the substrate 7. An embodiment according to FIG. 8A would e.g. be applicable for biasing the substrate solely by the hold-down device without establishing a respective pressure difference. FIG. 8B is analogous to FIG. 7B, but designed for an inverse pressure difference (pₐ being greater than p_{b}) and for a partial contact with protrusions 20, e.g. pins 20, protruding from the heating or cooling surface. In this embodiment a hold-down device is necessary to hold down the substrate 7 against the negative pressure difference force. In order to reduce gas flow leakage from the spacing beneath the substrate 7 to the overall load lock chamber volume, the lower edge of the hold-down device 21 is extended as depicted in FIG. 8B.

A rim or a downholder ring as addressed above helps for decoupling the pressure pₐ from p_{b}. A downholder ring allows to establish pₐ>p_{b}.

### LIST OF REFERENCE NUMERALS AND DESIGNATIONS

1 first treatment station

2 second treatment station

3 load lock chamber

4 load lock valve

5 controlled heat exchange device

6 vacuum pump of second treatment station

7 substrate

8 transport arrangement (for transport and handling)

9 degasser station (as a first treatment station 1)

10 vent of degasser station

11 pressure control members for load lock chamber

12 vacuum pump of pressure control members

13 opening in heating and/or cooling surface

14 pressure sensor for pₐ

15 pressure sensor for p_{b}

16 controller of feedback control system

17 unit setting the desired values

18 controls for heat exchange device 5

19 rim

20 height, protrusion, pin

21 hold-down device, downholder ring, clamping ring

p₁ pressure in first treatment station

p₂ pressure in second treatment station

T₁ temperature of substrate in first treatment station

T₂ temperature of substrate in second treatment station

pₐₜₘ. ambient atmospheric pressure

p_{b} prevailing pressure in load lock chamber

pₐ pressure at contacting area

Δp_{ab} pressure difference (p_{b}−pₐ)

Δt time span for heat exchange

CV control valve (also CV₁ and CV₂)

SV shut-off valve

What is claimed is:

1. A method of treating a substrate or of manufacturing a treated substrate, comprising following steps:
a) first treating a substrate in a first atmosphere of a first pressure, resulting in a first treated substrate having a first temperature;
b) subsequently, second treating said first treated substrate in a second atmosphere of a second pressure, starting said second treating at a second temperature of said first treated substrate and resulting in said treated substrate, wherein said second temperature is different from said first temperature and said second pressure is lower than said first pressure;
c) between steps a) and b) locking in said first treated substrate from said first atmosphere into said second atmosphere;
d) during said locking in, heating or cooling said first treated substrate from said first temperature towards said second temperature.

2. The method according to claim 1, wherein said first temperature is higher than said second temperature.

3. The method according to claim 1, wherein said first treating is degassing.

4. The method according to claim 1, wherein said first pressure is ambient atmospheric pressure.

5. The method according claim 1, comprising performing a transport of said first treated substrate between said first treating and said locking in.

6. The method according to claim 5, comprising performing at least a part of said transport in at least one of ambient atmospheric pressure and of ambient atmosphere.

7. The method according to claim 1, wherein said second pressure is a sub-atmospheric pressure.

8. The method according to claim 1, wherein pressure is reduced during said locking in at a pressure reduction rate and comprising providing a heat exchange time span during said locking in, wherein during said heat exchange time span said pressure reduction rate is reduced compared to said pressure reduction rate at least one of before and of after said heat exchange time span, at least along one extended surface side of said first treated substrate.

9. The method according to claim 1, comprising establishing an at least partial contact of said substrate and a heating or cooling surface during said locking in.

10. The method according to claim 9, wherein the at least partial contact is a surface to surface contact of said substrate and a heating or cooling surface during said locking in.

11. The method according to claim 9, wherein said contact is established by biasing said substrate onto said heating or cooling surface.

12. The method according to claim 11, wherein said biasing is performed by at least one of mechanically and of electrostatically.

13. The method according to claim 12, wherein biasing is performed mechanically by means of a hold-down device.

14. The method according to claim 11, wherein said biasing comprises establishing a pressure difference (Δp_{ab}) between a surface of said substrate facing said heating or cooling surface and a remainder of said surface of said substrate, by applying a lower pressure (pa) at a contacting area compared to a prevailing pressure (p_{b}) to which said remainder of said surface of said substrate is exposed.

15. The method according to claim 14, wherein said pressure difference Δp_{ab} is selected to be at least 300 Pa, or in the range of 300 Pa≤Δp_{ab}≤100000 Pa, or in the range of 500 Pa≤Δp_{ab}≤10000 Pa.

16. The method according to claim 14, wherein the prevailing pressure p_{b} is selected to be at least 400 Pa, or in the range of 400 Pa≤p_{b}≤100000 Pa, or in the range of 1000 Pa≤p_{b}≤20000 Pa.

17. The method according to claim 1, comprising establishing a first pressure between a substrate and a heating and/or cooling surface in a load lock chamber and establishing a second pressure in the remaining volume of said load lock chamber and negative feedback controlling a difference of said first and second pressures on a pre-set difference value or on a pre-set difference time course.

18. The method according to claim 1, comprising removing said second treated substrate from said second treating via locking out at the same place as performing said locking in.

19. The method according to claim 18 comprising performing during said locking out a further heating or cooling of said second treated substrate.

20. The method according to claim 19, said further heating or cooling being a cooling or heating performed by same means as said cooling or heating performed during said locking in.

21. The method according to claim 1, comprising initiating lowering pressure for said locking in and initiating cooling or heating a predetermined time span after initiating said pressure lowering.

22. A method of heating or cooling a floppy substrate in vacuum comprising pressing said substrate onto a heating or cooling surface by generating a drop of pressure across said substrate directed towards said heating or cooling surface.

23. A substrate treatment apparatus, comprising:
a) a first treatment station for at least one substrate and constructed to treat said at least one substrate in a first atmosphere at a first pressure and comprising a first station output for a first treated substrate;
b) a second treatment station for at least one substrate and constructed to treat said at least one first treated substrate in a second atmosphere at a second pressure which is lower than said first pressure and comprising a second station input for a first treated substrate;
c) a load lock chamber interconnected between said first station output and said second station input;
d) a controlled heat exchange device in said load lock chamber adapted to exchange heat with a first treated substrate in said load lock chamber, controlled to be enabled as said first treated substrate is load-locked through said load lock chamber from said first treatment station to said second treatment station.

24. The apparatus according to claim 23, wherein said controlled heat exchange device comprises a heating or cooling unit.

25. The apparatus according to claim 23, wherein said controlled heat exchange device comprises a heating-cooling unit.

26. The apparatus according to claim 23, wherein said first treatment station is a degasser station.

27. The apparatus according to claim 23, wherein said first pressure is ambient atmospheric pressure.

28. The apparatus according to claim 23, further comprising a transport arrangement interconnected between said first station output and said load lock chamber.

29. The apparatus according to claim 28, wherein said transport arrangement is designed for transporting said substrate in at least one of ambient atmospheric pressure and of ambient atmosphere.

30. The apparatus according to claim 23, wherein said second treatment station is a sub-atmospheric treatment station.

31. The apparatus according to claim 23, wherein the heat exchange device comprises a heating and/or cooling surface.

32. The apparatus according to claim 31, further comprising a biasing arrangement constructed to bias a substrate onto said heating and/or cooling surface.

33. The apparatus according to claim 32, wherein said biasing arrangement comprises pressure control members adapted to control a pressure difference between a pressure along said heating and/or cooling surface with put-on substrate and a prevailing pressure in said load lock chamber distant from said heating and/or cooling surface.

34. The apparatus according to claim 33, wherein said pressure control members comprise a first pumping line arrangement connected by a conduit to at least one opening in said heating and/or cooling surface, and a second pumping line arrangement connected by another conduit to at least one further opening to said load lock chamber distant from said heating and/or cooling surface.

35. The apparatus according to claim 34, wherein the at least one opening in said heating and/or cooling surface branches out in a pattern of grooves in the heating and/or cooling surface.

36. The apparatus according to claim 34, wherein said first and said second pumping line arrangements are branches from a common pumping suction port.

37. The apparatus according to claim 34, wherein at least one of said first and second pumping line arrangements comprises a pressure-control valve or a flow-control valve.

38. The apparatus according to claim 33, wherein a negative feedback control system is provided for controlling at least during a predetermined time span a pressure difference (Δp_{ab}) between a pressure along said heating and/or cooling surface with put-on substrate and a prevailing pressure in said load lock chamber distant from said heating and/or cooling surface on a desired value or to follow a desired time course.

39. The apparatus according to claim 23, wherein the heat exchange device comprises a substrate carrier with a substrate carrier surface and a rim or a clamping ring along the periphery of said substrate carrier surface.

40. The apparatus according to claim 23, wherein the heat exchange device comprises conduits for a heating fluid and/or for a cooling fluid.

41. The apparatus according to claim 23, said second station input being also a second station output, and said load lock chamber being constructed for bidirectional substrate handling operation.

42. The apparatus of claim 23, comprising in said load lock chamber:
a heating and/or cooling surface;
a substrate carrier for a substrate, a substrate on said carrier defining an interspace with said heating and/or cooling surface;
a first pressure sensor operatively connected to said interspace;
a second pressure sensor operatively connected to the remainder of said load lock chamber;
a negative feedback control loop with a controller adapted to control a difference of pressures measured by said first and second pressure sensors to be equal to a pre-set pressure difference value or to follow a pre-set pressure difference time course.
